(19) United States
(12) Patent Application Publication
(10) Pub. No.: US 2026/0190920 A1
(43) Pub. Date: Jul. 2, 2026

(54) OPTICAL MODULE AND SUBSTRATE PROCESSING APPARATUS INCLUDING SAME

(71) Applicant: SEMES CO., LTD., Cheonan-si (KR)

(72) Inventors: Sang Mo YANG, Seoul (KR); Jun Yeop LEE, Yongin-si (KR); Ji Young LEE, Suwon-si (KR)

(73) Assignee: SEMES CO., LTD., Cheonan-si (KR)

(21) Appl. No.: 19/433,181

(22) Filed: Dec. 26, 2025

(30) Foreign Application Priority Data
Dec. 27, 2024 (KR) 10-2024-0198519

(51) Int. Cl. H10P 72/00

(52) U.S. Cl. CPC H10P 72/06; H10P 72/0404

(57) ABSTRACT

Disclosed are an optical module and a substrate processing apparatus including the same. The substrate processing apparatus includes an optical module, in which the optical module includes: a camera; a direction changing mirror placed in a position facing the camera; a first reflection mirror; a second reflection mirror; and a mirror driver configured to drive the direction changing mirror, and the direction changing mirror is provided so as to be position-changeable between a first position and a second position, the first position is a position where the camera photographs the inner space through the first reflection mirror, and the second position is a position where the camera photographs the inner space through the second reflection mirror. Accordingly, the position of the component may be measured during the process and the position may be corrected in real time.

### CROSS-REFERENCE TO RELATED APPLICATION

This application claims priority to and the benefit of Korean Patent Application No. 10-2024-0198519 filed in the Korean Intellectual Property Office on Dec. 27, 2024, the entire contents of which are incorporated herein by reference.

### TECHNICAL FIELD

The present invention relates to an optical module and a substrate processing apparatus including the same, and more specifically, to an optical module capable of photographing an entire treatment space with a single optical module and a substrate processing apparatus including the same.

### BACKGROUND ART

A substrate processing apparatus used in manufacturing semiconductor devices and flat panel panels includes a chamber having a complex internal structure to process wafers or glass substrates, and various components are precisely arranged therein. Each component has a unique position and moves to a position required during the process.

Due to the recent precision and advancement of the semiconductor industry, high-level processes, such as the formation of nanometer-level circuit patterns and the manufacturing of 3D semiconductor devices have increased, and the impact of the position of components in the chamber on the process results has increased. As a result, the technology for measuring and controlling the positions of major components during the process in real time is essential, which may improve process stability, product quality, and yield.

However, as the chamber is miniaturized in an effort to reduce the physical size (footprint) of the equipment, there is a problem that it is difficult to measure and control the position of the component due to the lack of an inner space 310a and increased interference between components.

### SUMMARY OF THE INVENTION

The present invention has been made in an effort to provide an optical module capable of photographing components provided in an inner space of a chamber with a single camera and a substrate processing apparatus including the same.

The present invention has also been made in an effort to provide an optical module capable of measuring a position of a component in real time without opening a chamber and a substrate processing apparatus including the same.

The present invention has also been made in an effort to provide an optical module capable of measuring a position of a component during a process and correcting the position in real time, and a substrate processing device including the same.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a housing providing an inner space; a cup unit placed in the inner space and providing a treatment space for processing the substrate; a spin chuck configured to support the substrate in the treatment space; a nozzle unit configured to supply a treatment liquid to the substrate supported on the spin chuck; and an optical module for photographing the inner space, wherein the optical module includes: a camera; a direction changing mirror placed in a position facing the camera; a first reflection mirror; a second reflection mirror; and a mirror driver configured to drive the direction changing mirror, and the direction changing mirror is provided so as to be position-changeable between a first position and a second position, the first position is a position where the camera photographs the inner space through the first reflection mirror, and the second position may be a position where the camera photographs the inner space through the second reflection mirror.

According to the exemplary embodiment of the present invention, wherein the camera and the direction changing mirror are arranged in a first direction, and the first reflection mirror and the direction changing mirror, and the direction changing mirror and the second reflection mirror may be each arranged in a second direction perpendicular to the first direction.

According to the exemplary embodiment of the present invention, wherein the first reflection mirror, the direction changing mirror, and the second reflection mirror may be sequentially arranged along the second direction.

According to the exemplary embodiment of the present invention, wherein the mirror driver may rotates the direction changing mirror about the first direction as an axis.

According to the exemplary embodiment of the present invention, wherein the optical module includes: a rotating plate provided to be rotatable; and a support fixedly installed on the rotating plate, and the support has an inclined surface, the inclined surface is provided to face the camera, and the direction changing mirror may be installed on the inclined surface.

According to the exemplary embodiment of the present invention, wherein the optical module further includes a frame having a space in which the first reflection mirror, the second reflection mirror, and the direction changing mirror are disposed, and the frame has an opening may formed at each of a position facing the first reflection mirror and a position facing the second reflection mirror.

According to the exemplary embodiment of the present invention, wherein the nozzle unit includes: a first nozzle configured to discharge a first liquid to a center of the substrate supported by the spin chuck; and a second nozzle configured to discharge a second liquid to an edge of the substrate supported by the spin chuck, the optical module is provided to photograph the first nozzle located in a first space and the second nozzle located in a second space, the first space includes a position where the first liquid is discharged from the first nozzle, and the second space may include a position where the second liquid is discharged from the second nozzle.

According to the exemplary embodiment of the present invention, wherein the first liquid is photoresist, and the second liquid may be a removal liquid that removes the first liquid from an edge area of the substrate.

According to the exemplary embodiment of the present invention, wherein the first space may include a central axis of the spin chuck.

According to the exemplary embodiment of the present invention, wherein the first reflection mirror and the second reflection mirror are each rotatably provided, and the first space or the second space may be photographed according to rotation of the first reflection mirror and the second reflection mirror.

According to the exemplary embodiment of the present invention, wherein the first reflection mirror and the second reflection mirror rotate about a third direction as an axis, and the third direction may be perpendicular to the first direction and the second direction.

According to the exemplary embodiment of the present invention, wherein the camera includes: a lens; and an image sensor configured to form an image, and the lens may be a telephoto lens.

According to the exemplary embodiment of the present invention, further comprising: controller, wherein the nozzle unit further includes a nozzle driver configured to drive the first nozzle and the second nozzle, the controller controls the optical module to determine a current position of at least one of the first nozzle and the second nozzle by photographing at least one of the first nozzle and the second nozzle, and when the current position does not match a reference position, the controller controls the nozzle driver to move at least one of the first nozzle and the second nozzle from the current position to the reference position, and the reference position may be a preset position.

Further, an exemplary embodiment of the present disclosure, an optical module comprising: a frame having an inner space; a camera installed in the frame; a direction changing mirror placed in a position facing the camera in the inner space; a first reflection mirror provided to be rotatable in the inner space; a second reflection mirror provided to be rotatable in the inner space; and a mirror driver configured to drive the first reflection mirror, the second reflection mirror, and the direction changing mirror, the frame has an opening formed at each of a position facing the first reflection mirror and a position facing the second reflection mirror, the first reflection mirror and the second reflection mirror are rotated to change an area photographed by the camera, the direction changing mirror is provided so as to be position-changeable between a first position and a second position, the first position is a position where the camera photographs an area through the direction changing mirror and the first reflection mirror, and the second position may be a position where the camera photographs an area through the direction changing mirror and the second reflection mirror.

According to the exemplary embodiment of the present invention, wherein the camera and the direction changing mirror may be arranged in a first direction, and the first reflection mirror and the direction changing mirror, and the direction changing mirror and the second reflection mirror are each arranged in a second direction perpendicular to the first direction.

According to the exemplary embodiment of the present invention, wherein the first reflection mirror and the second reflection mirror rotate about a third direction as an axis, and the third direction is perpendicular to the first direction and the second direction, and the direction changing mirror may rotates about the first direction as an axis.

According to the exemplary embodiment of the present invention, further comprising: rotating plate provided to be rotatable; and a support fixedly installed on the rotating plate, and the support has an inclined surface, the inclined surface is provided to face the camera, and the direction changing mirror may be installed on the inclined surface.

Further, an exemplary embodiment of the present disclosure, an apparatus for processing a substrate, the apparatus comprising: a housing providing an inner space; a cup unit placed in the inner space and providing a treatment space for processing the substrate; a spin chuck configured to support the substrate in the treatment space; a nozzle unit configured to supply a treatment liquid to the substrate supported on the spin chuck; and an optical module for photographing the inner space, the optical module includes: a frame having a space therein; a camera provided within the frame; a direction changing mirror placed in a position facing the camera; a first reflection mirror provided to be rotatable; a second reflection mirror provided to be rotatable; a mirror driver configured to drive the first reflection mirror, the second reflection mirror, and the direction changing mirror; a rotating plate provided to be rotatable; and a support fixedly installed on the rotating plate, and the support has an inclined surface, the inclined surface is provided to face the camera, the direction changing mirror is installed on the inclined surface, the frame has an opening formed at each of a position facing the first reflection mirror and a position facing the second reflection mirror, the first reflection mirror and the second reflection mirror are rotated to change an area photographed by the camera, the direction changing mirror is provided so as to be position-changeable between a first position and a second position, the first position is a position where the camera photographs the inner space through the first reflection mirror, and the second position is a position where the camera photographs the inner space through the second reflection mirror, and the camera and the direction changing mirror are arranged in a first direction, and the first reflection mirror and the direction changing mirror, and the direction changing mirror and the second reflection mirror are each arranged in a second direction perpendicular to the first direction, the first reflection mirror and the second reflection mirror rotate about a third direction as an axis, and the third direction is perpendicular to the first direction and the second direction, and the direction changing mirror may rotates about the first direction as an axis.

According to the exemplary embodiment of the present invention, wherein the nozzle unit includes: a first nozzle configured to discharge a photoresist to a center of the substrate supported by the spin chuck; and a second nozzle configured to discharge a removal liquid that remove the photoresist applied on an edge of the substrate supported by the spin chuck, the optical module is provided to photograph the first nozzle located in a first space and the second nozzle located in a second space, the first space includes a position where the photoresist is discharged from the first nozzle, and the second space may include a position where the removal liquid is discharged from the second nozzle.

According to the exemplary embodiment of the present invention, wherein the nozzle unit further includes a nozzle driver configured to drive the first nozzle and the second nozzle, the controller controls the optical module to photograph at least one of the first nozzle and the second nozzle to determine a current position of at least one of the first nozzle and the second nozzle, when the current position does not match a reference position, the controller controls the nozzle driver to move at least one of the first nozzle and the second nozzle from the current position to the reference position, and the reference position may be a position on a central axis of the spin chuck.

According to the exemplary embodiment of the present invention, the present invention may photograph components provided in an inner space of a chamber with a single camera.

Further, the present invention may measure a position of a component in real time without opening a chamber.

Further, the present invention may measure a position of a component during a process and correct the position in real time.

Effects of the present disclosure are not limited to those described above and effects not stated above will be clearly understood to those skilled in the art from the specification and the accompanying drawings.

### BRIEF DESCRIPTION OF THE DRAWINGS

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating an optical module according to an exemplary embodiment of the present invention.

FIGS. 2 and 3 are diagrams illustrating a state in which a direction changing mirror rotates to photograph a photographing target from different directions.

FIG. 4 is a cross-sectional view schematically illustrating an example of a liquid treating chamber which is a substrate processing apparatus according to an exemplary embodiment of the present invention.

FIG. 5 is a diagram schematically illustrating a state in which an optical module according to an exemplary embodiment of the present invention acquires a first image and a second image for a first space and a second space.

FIG. 6 is a diagram illustrating a positional relationship between a first nozzle and a spin chuck.

FIG. 7 is a diagram illustrating a positional relationship between a second nozzle and a spin chuck.

FIG. 8 is a diagram illustrating a positional relationship between an outer cup and the spin chuck.

### DETAILED DESCRIPTION

In the present exemplary embodiment, a wafer is described as an example as an object to be treated. However, the technical idea of the present invention may be applied to devices used for treating other types of substrates other than wafers as objects to be treated.

Hereinafter, an exemplary embodiment of the present invention will be described with reference to the accompanying drawings.

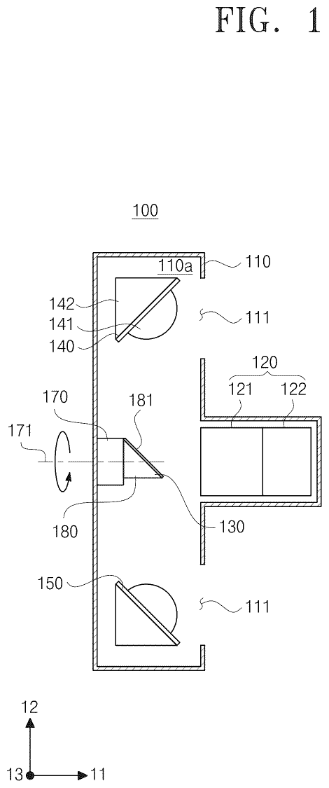

FIG. 1 is a diagram schematically illustrating an optical module according to an exemplary embodiment of the present invention. Referring to FIG. 1, an optical module 100 may include a frame 110, a camera 120, a direction changing mirror 130, a first reflection mirror 140, a second reflection mirror 150, a mirror driver 160, a rotating plate 170, and a support 180.

The frame 110 has an inner space 110a. The camera 120, the direction changing mirror 130, the first reflection mirror 140, the second reflection mirror 150, the rotating plate 170, and the support 180 may be located in the inner space 110a of the frame 110. The frame 110 is provided in a shape having a first direction 11 and a second direction 12 as a longitudinal direction. The first direction 11 and the second direction 12 may be perpendicular to each other. According to an example, the frame 110 may be provided in a ‘ [symbol] ’ shape when viewed from above. The camera 120 and the direction changing mirror 130 may be arranged in the first direction 11. The first reflection mirror 140 and the direction changing mirror 130, and the direction changing mirror 130 and the second reflection mirror 150 may be arranged in the second direction 12, respectively. The first reflection mirror 140, the direction changing mirror 130, and the second reflection mirror 150 may be sequentially arranged along the second direction 12.

Openings 111 may be formed in the frame 110 at a position facing the first reflection mirror 140 and a position facing the second reflection mirror 150. Light reflected from a photographing target T may be incident on the first reflection mirror 140 and the second reflection mirror 150 through the openings 111.

The camera 120 is provided within the frame 110. The camera 120 photographs the photographing target T. The camera 120 may photograph the photographing target T through the first reflection mirror 140 and the direction changing mirror 130. Also, the camera 120 may photograph the photographing target T through the second reflection mirror 150 and the direction changing mirror 130.

The camera 120 may include a lens 121 and an image sensor 122. The lens 121 and the image sensor 122 may be arranged along the first direction 11. The lens 121 may be provided closer to the direction changing mirror 130 than the image sensor 122. The direction changing mirror 130, the lens 121, and the image sensor 122 may be sequentially arranged. Accordingly, light passing through the direction changing mirror 130 reaches the image sensor 122 through the lens 121.

The lens 121 may be provided to form an image having a resolution capable of analyzing and calculating the position of the photographing target T. According to an example, the lens 121 may be a telephoto lens. The resolution of the image may be improved by the telephoto lens. It is possible to more accurately determine the position of the photographing target through the image with the improved resolution.

The image sensor 122 receives light through the lens 121 and converts light energy into an electrical signal to generate a digital image. The image sensor 122 may be a Charge-Coupled Device (CCD) sensor or a Complementary Metal-Oxide Semiconductor (CMOS) sensor. The image generated by the image sensor 122 may be configured to be transmitted to an external device. The image sensor 122 and the external device may be connected to each other by a wired or wireless electronic communication link.

The direction changing mirror 130 is disposed at a position facing the camera 120. The direction changing mirror 130 reflects the light reflected from the first reflection mirror 140 or the second reflection mirror 150 to the camera 120. The direction changing mirror 130 is rotatably provided by the mirror driver 160. The direction changing mirror 130 may be installed on the support 180 installed on the rotating plate 170. The rotating plate 170 is rotatably provided by the mirror driver 160. The rotating plate 170 may rotate with respect to a central axis 171 of the rotating plate. The rotating plate 170 may be provided such that the central axis 171 of the rotating plate has the first direction 11. The support 180 is installed on an upper surface of the rotating plate 170. The support 180 has an inclined surface 181. The inclined surface 181 is provided to face the camera 120. The direction changing mirror 130 is installed on the inclined surface 181. Accordingly, the direction changing mirror 130 may be rotated about the first direction 11 as an axis together with the rotating plate 170. The direction changing mirror 130 is rotated to reflect light reflected from the first reflection mirror 140 or the second reflection mirror 150 to the camera 120.

The direction changing mirror 130 may be provided to be position-changeable between a first position R1 and a second position R2. The position change between the first position R1 and the second position R2 may be performed through rotation about the center axis 171 of the rotating plate as an axis. A position difference between the first position R1 and the second position R2 may be 180°. The first position R1 may be a position where the direction changing mirror 130 faces the first reflection mirror 140. The first position R1 may be a position where the camera 120 photographs through the direction changing mirror 130 and the first reflection mirror 140. The second position R2 may be a position where the direction changing mirror 130 faces the second reflection mirror 150. The second position R2 may be a position where the camera 120 photographs through the direction changing mirror 130 and the second reflection mirror 150.

The first reflection mirror 140 is provided in the inner space 110a of the frame. The first reflection mirror 140 reflects light entering through the opening 111 to the direction changing mirror 130. The first reflection mirror 140 is rotatably provided. The first reflection mirror 140 may be provided to be rotatable about the third direction 13 as an axis. The third direction 13 is provided in a direction perpendicular to the first direction 11 and the second direction 12. For example, a rotating plate 141 having the third direction 13 as the center axis may be provided, a support 142 may be installed on the rotating plate 141, and the first reflection mirror 140 may be installed on the support 142. The support 142 has a shape of a right triangle when viewed from above, and the first reflection mirror 140 may be installed on the hypotenuse of a right triangle. However, the present invention is not limited thereto, and it is sufficient that the first reflection mirror 140 is installed to be rotatable in the third direction 13.

The second reflection mirror 150 is provided in the inner space 110a of the frame. The second reflection mirror 150 reflects light entering through the opening 111 to the direction changing mirror 130. The second reflection mirror 150 is rotatably provided. The second reflection mirror 150 may be provided to be rotatable about the third direction 13 as an axis. For example, a rotating plate 141 having the third direction 13 as the center axis may be provided, a support 142 may be installed on the rotating plate 141, and the second reflection mirror 150 may be installed on the support 142. The support 142 has a shape of a right triangle when viewed from above, and the second reflection mirror 150 may be installed on the hypotenuse of a right triangle. However, the present invention is not limited thereto, and it is sufficient that the second reflection mirror 150 is installed to be rotatable in the third direction 13.

The first reflection mirror 140 and the second reflection mirror 150 may be rotated to at least a range in which light incident on the opening 111 may be reflected by the direction changing mirror 130. Accordingly, according to the rotation of the first reflection mirror 140 and the second reflection mirror 150, the photographing target may be changed in the first space or the second space. The first reflection mirror 140 and the second reflection mirror 150 may be rotated to change a region to be photographed. The first reflection mirror 140 and the second reflection mirror 150 may be provided to be rotated by the mirror driver 160.

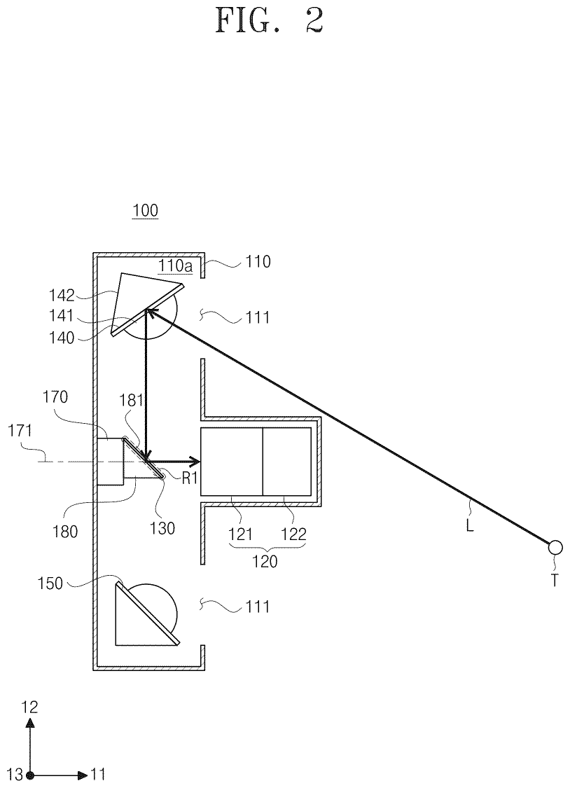

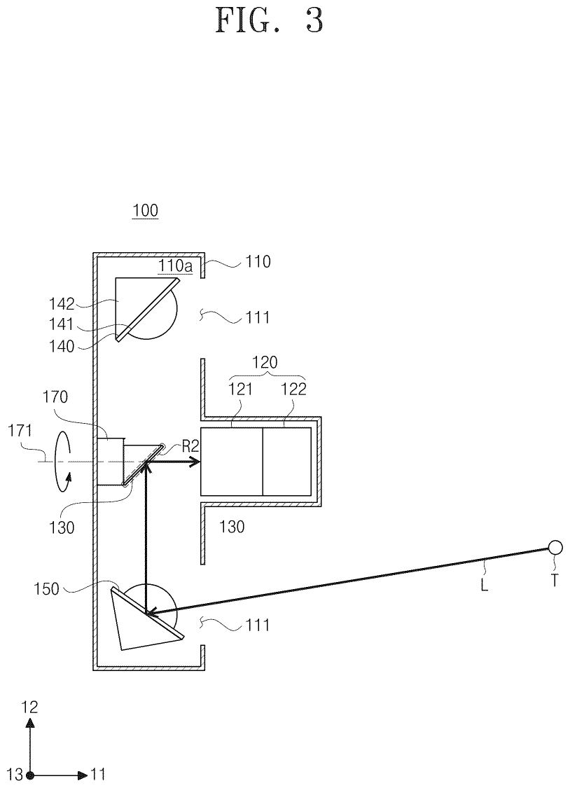

FIGS. 2 and 3 are diagrams illustrating a state in which the direction changing mirror rotates to photograph a photographing target from different directions. Referring to FIGS. 2 and 3, when the camera 120 photographs a photographing target through the first reflection mirror 140, the direction changing mirror 130 is positioned at a first position R1. The light L reflected from the photographing target T is incident to the opening 111 and is reflected to the camera 120 through the first reflection mirror 140 and the direction changing mirror 130. Accordingly, the light L is incident on the camera 120 and a first image is formed. Further, when the camera 120 photographs a photographing target through the second reflection mirror 150, the direction changing mirror 130 is positioned at a second position R2. The light L reflected from the photographing target T is incident to the opening 111 and is reflected to the camera 120 through the second reflection mirror 150 and the direction changing mirror 130. Accordingly, the light L is incident on the camera 120 and a second image is formed.

In the above-described example, it has been described that the number of photographing targets T is singular, but the present invention is not limited thereto and there may be a plurality of photographing targets T. When the optical module 100 photographs an image of a predetermined area, the photographing target T is located within the predetermined area, and another photographing target adjacent to the photographing target T exists within the predetermined area, there may be a plurality of photographing targets T.

As described above, the optical module 100 may acquire an image in a plurality of directions with respect to one photographing target T. The acquired image may be used for analyzing the photographing target T. Here, the range of the analysis may include a size and ratio of a photographing target, a geometric information extraction, a three-dimensional structure, a location of the photographing target, a relative location between the photographing targets, and the like.

Hereinafter, a substrate processing apparatus including the optical module 100 will be described. According to an example, the substrate processing apparatus may be a liquid treating chamber 300.

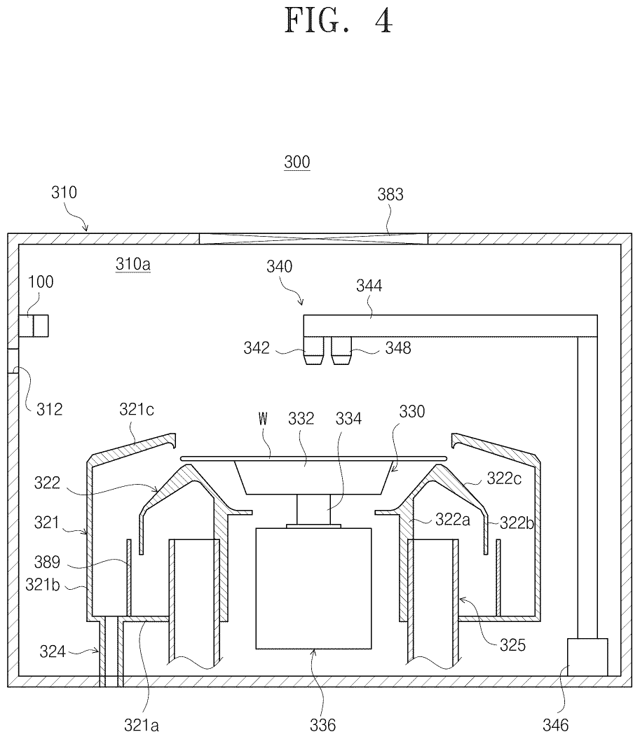

FIG. 4 is a cross-sectional view schematically illustrating an example of a liquid treating chamber which is a substrate processing apparatus according to an exemplary embodiment of the present invention. Referring to FIG. 4, the liquid treating chamber 300 may include a housing 310, a cup unit 320, a support unit 330, a nozzle unit 340, and an optical module 100.

The housing 310 is provided in a rectangular cylindrical shape having an inner space 310a. An opening 312 is formed in one side of the housing 310. The opening 312 functions as a passage through which the substrate W enters and exits. A door (not illustrated) is installed in the opening 312, and the door opens and closes the opening.

A cup unit 320 is provided in the inner space 310a of the housing 310. The cup unit 320 has a treatment space with an open top. The cup unit 320 may include an outer cup 321 and a guide cup 322. The outer cup 321 has a bottom wall 321a, a side wall 321b, and an upper wall 321c. The inside of the cup unit 320 includes an upper treatment space and a lower exhaust space.

The bottom wall 321a is provided in a circular shape and has an opening at the center thereof. The side wall 321b extends upward from the outer end of the bottom wall 321a. The side wall 321b is provided in a ring shape and is provided perpendicular to the bottom wall 321a. For example, the side wall 321b extends to the same height as an upper surface of the spin chuck 332, or to a height slightly lower than an upper surface of the spin chuck 332. The upper wall 321c has a ring shape and has an opening at the center thereof. The upper wall 321c is provided to be inclined upward from the upper end of the side wall 321b toward the central axis of the cup unit 320.

Among the treatment spaces, a space below the spin chuck 332 may be provided as an exhaust space. According to an example, the exhaust space may be defined by the guide cup 322. The guide cup 322 is provided inside the outer cup 321, and the guide cup 322 may have an inner wall 322a, an outer wall 322b, and an upper wall 322c. A space surrounded by the outer wall 322b, the upper wall 322c, and the inner wall 322a of the guide cup 322 and/or a space below the outer wall 322 may be provided as an exhaust space.

The inner wall 322a has a through hole penetrating in the vertical direction. The inner wall 322a is disposed to surround the support unit 330. The inner wall 322a may minimize the exposure of the driver 336 to airflow in the treatment space. The shaft 334 or/and the driver 336 of the support unit extend in the vertical direction through the through hole. The outer wall 322b is disposed to be spaced apart from the inner wall 322a and to surround the inner wall 322a. The outer wall 322b is positioned to be spaced apart from the side wall 321b of the outer cup 321. The inner wall 322a is disposed to be spaced apart upward from the bottom wall 321a of the outer cup. The upper wall 322c connects the upper end of the outer wall 322b and the upper end of the inner wall 322a. The upper wall 322c is provided to have a ring shape. According to an example, the upper wall 322c has a convex shape upward.

The cup unit 320 may further include a gas-liquid separation plate 323. The gas-liquid separation plate 323 may extend upward from the bottom wall 321a of the cup unit 320. The gas-liquid separation plate 323 may be provided in a ring shape. When viewed from above, the gas-liquid separation plate 323 may be positioned between the side wall 321b of the outer cup and the outer wall 322b of the guide cup. The upper end of the gas-liquid separation plate 323 may be positioned lower than the lower end of the outer wall 322b of the guide cup 322.

A discharge pipe 324 and an exhaust pipe 325 for discharging a first liquid are connected to the bottom wall 321a of the outer wall. The discharge pipe 324 may be connected to the cup unit 320 from the outside of the gas-liquid separation plate 323. The exhaust pipe 325 may be connected to the cup unit 320 from the inside of the gas-liquid separation plate 323.

The support unit 330 supports the substrate W in the treatment space of the cup unit 320. The support unit 330 includes a spin chuck 332, a shaft 334, and a driver 336. A top surface of the spin chuck 332 is provided in a circular shape. The spin chuck 332 has a diameter smaller than that of the substrate W. A plurality of vacuum holes 332b is provided on a top surface of the spin chuck 332. The vacuum hole 332b is provided such that the spin chuck 332 supports the substrate W by vacuum pressure. At least one of a plurality of vacuum holes 332b is provided on the central axis 332a of the spin chuck. According to an example, a plurality of vacuum holes 332b may be arranged to radiate with respect to a central axis 332a of the spin chuck. The shaft 334 is coupled to a center of a bottom surface of the spin chuck 332, and the shaft 334 is connected to the driver 336. The driver 336 rotates the spin chuck 332 about a central axis 332a of the spin chuck as an axis. According to an example, the driver 336 may include a motor. Also, the driver 336 may further include a lifting driver configured to adjust a relative height of the spin chuck 332 and the cup unit 320.

The nozzle unit 340 may include a nozzle 342, a nozzle support 344, and a nozzle driver 346. The nozzle 342 may be moved onto the central axis 332a of the spin chuck supporting the substrate W and may discharge the first liquid onto the substrate W. According to an example, the first liquid may be a photoresist. The nozzle 342 is supported by the nozzle support 344.

The nozzle driver 346 moves the nozzle 342 between a process position and a standby position. The process position may be a position where the first liquid is supplied from the nozzle 342 to the substrate W placed on the spin chuck 332. According to an example, the process position may be a position where the nozzle 342 is located on the central axis 332a of the spin chuck. The standby position is a position where the nozzle 342 which has completed supplying the first liquid waits in a home port (not illustrated). The home port is provided in the inner space 310a and provides a space in which the nozzle 342 waits. The process position of the nozzle 342 may be a reference position of the first nozzle 342 to be described later.

A first liquid supply source and a first liquid supply line, which are not illustrated, may be connected to the nozzle 342. The first liquid supply source stores and/or supplies the first liquid. The first liquid supply line connects the first liquid supply source and the nozzle 342. A pump, a filter, a valve, and the like required for supplying the first liquid may be installed in the first liquid supply line.

Selectively, the nozzle 342 may be a first nozzle, and the nozzle unit 340 may further include a second nozzle 348. The second nozzle 348 may discharge a second liquid, which is different from the first liquid discharged from the first nozzle 342, to an edge area of the substrate W. According to an example, the second liquid may be a removal liquid for removing the first liquid. The removal liquid may be an Edge Bead Removal (EBR) solution. According to an example, the EBR solution may be a liquid including an organic solvent, an alkaline solution, or a thinner. Like the first nozzle 342, the second nozzle 348 is provided to be moved between the process position and the standby position by the nozzle driver 346. The process position is a position where the second nozzle 348 moves to an edge area of the substrate W to discharge the second liquid, and the standby position is a position where the second nozzle 348 which has completed supplying the second liquid waits in the home port 360. The process position of the second nozzle 348 may be a position spaced apart from the central axis 332a of the spin chuck by a predetermined distance D. The process position of the second nozzle 348 may be a reference position of the second nozzle 348 to be described later.

The second nozzle 348 may be supported and driven together with the first nozzle 342 by the nozzle support 344, or may be supported and driven by a separate support and driver.

A fan filter unit 383 for supplying descending airflow to the inner space 310a may be disposed on an upper wall of the housing 310. The fan filter unit 383 has a fan for introducing external air into the inner space 310a and a filter for filtering external air.

The optical module 100 may be installed in the housing 310. In the following description, the optical module 100 will be described by referring to reference numerals illustrated in FIGS. 1 to 3, and redundant descriptions are omitted.

The optical module 100 may be installed on an inner wall of the housing 310. Also, the optical module 100 may be installed above the opening 312. The optical module 100 is provided to photograph the inner space 310a of the liquid treating chamber 300. The inner space 310a includes a first space S1 and a second space S2, and the optical module 100 is provided to photograph the first space S1 and the second space S2.

The optical module 100 may photograph the first space S1 or the second space S2 according to rotation of the first reflection mirror 140 and the second reflection mirror 150. The first space S1 may be a space including the process position of the first nozzle 342. Also, the first space S1 may be a space including the first nozzle 342 and the spin chuck 332 located at the process position. The second space S2 may be a space including the process position of the second nozzle 348. Also, the second space S2 may be a space further including the edge area of the substrate W and an end portion of the upper wall 321c of the outer cup.

In addition, the optical module 100 may acquire a first image and a second image according to the rotation of the direction changing mirror 130. The first image is an image acquired through the first reflection mirror 140, and the second image is an image acquired through the second reflection mirror 150. Since the first reflection mirror 140 and the second reflection mirror 150 are spatially spaced apart, the first image and the second image may represent shapes of the same target in different directions.

Hereinafter, a method of controlling the optical module 100 using the controller 900 will be described. The method described below may be performed by the optical module 100 described with reference to FIGS. 1 to 4 and the liquid treating chamber 300 including the same. Accordingly, hereinafter, a method of controlling the optical module 100 according to an exemplary embodiment will be described by quoting reference numerals illustrated in FIGS. 1 to 4.

The controller 900 may include a process controller formed of a microprocessor that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treating recipe, for executing the process in each component according to various data and treating conditions. Further, the user interface and the storage unit may be connected to the process controller. The storage unit may include a storage medium, and the storage medium may be provided as a portable disk, such as a hard disk, a CD-ROM, or a DVD, or a semiconductor memory, such as a flash memory.

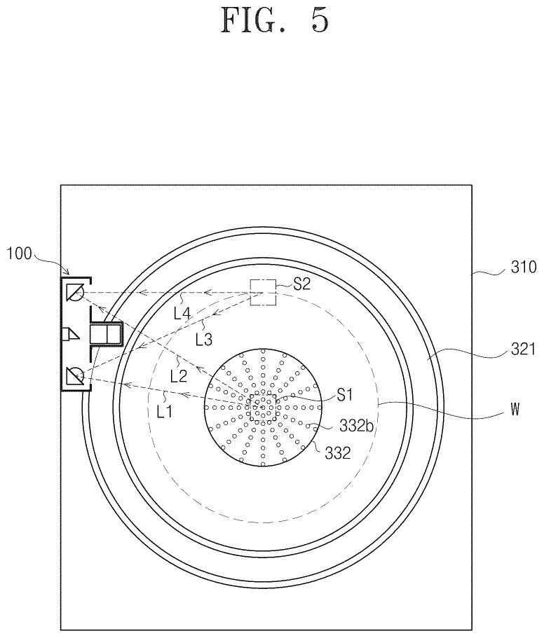

FIG. 5 is a diagram schematically illustrating a state in which the optical module according to the exemplary embodiment of the present invention acquires a first image and a second image for a first space and a second space. Referring to FIG. 5, the controller 900 may acquire a first image and a second image by controlling the direction changing mirror 130. Further, the controller 900 may control the first reflection mirror 140 and the second reflection mirror 150 to acquire images for the first space S1 and the second space S2. The first image may be an image photographed through the first reflection mirror 140, and the second image may be an image acquired by photographing the same area as the first image through the second reflection mirror 150. That is, the first image and the second image may be images photographed in different directions for the same photographing target. For example, the first image for the first space S1 may be an image acquired by light L1, the second image for the first space S1 may be an image acquired by light L2, the first image for the second space S2 may be an image acquired by light L3, and the second image for the second space S2 may be an image acquired by light L4.

The controller 900 may determine the location of the photographing target by using the first image and the second image. When there is a plurality of photographing targets, relative positions of the photographing targets may be determined. A method of determining a position may be performed using a known technique of determining a position of a photographing target using a plurality of images. For example, photogrammetry, triangulation, stereo vision, and the like may be used. The controller 900 may include a storage medium in which algorithms, programs, and the like are stored to utilize the above-described methods.

The driving control algorithm of each configuration of the substrate processing apparatus stored in the controller 900 includes information on the location of each configuration when processing the substrate W. For example, the driving control algorithm may include information (hereinafter, referred to as a “reference position”) on the positions of the first nozzle 342, the second nozzle 348, the spin chuck 332, and the outer cup 321 and the relative positions between the first nozzle 342, the second nozzle 348, the spin chuck 332, and the outer cup 321. The controller 900 controls the optical module 100 and the drivers 336 and 346 before the substrate W is loaded into the treatment space to determine the position of each component in advance, and the user may set the reference position in advance and store the set reference position in the controller 900.

Hereinafter, a method of determining and adjusting the current positions of the first nozzle 342, the second nozzle 348, the spin chuck 332, and the outer cup 321 will be described.

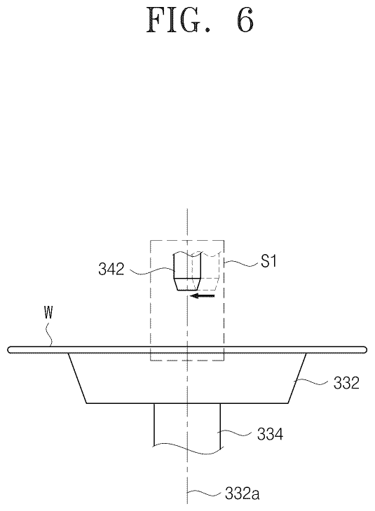

FIG. 6 is a diagram illustrating a positional relationship between the first nozzle and the spin chuck. Referring to FIG. 6, the reference position of the first nozzle 342 may be a position on the central axis 332a of the spin chuck. The reference position of the first nozzle 342 may be acquired in advance by the controller 900 before the substrate W is loaded into the treatment space. The controller 900 acquires a first image and a second image for the spin chuck 332 before the substrate W is loaded into the treatment space. Even if only the central region, which is a partial region of the spin chuck 332, is included in the first image and the second image, the position of the central axis 332a of the spin chuck may be specified through the vacuum hole 332b formed on the upper surface of the spin chuck 332. The reference position of the first nozzle 342 may be recorded in an image acquired by the optical module 100 or may be stored as a coordinate in three dimensions. The reference position of the first nozzle 342 may be the process position of the first nozzle 342.

The controller 900 may determine the current position of the first nozzle 342 located in the first space S1 and compare the current position with a reference position. The controller 900 may adjust the position of the first nozzle 342 with respect to the center axis 332a of the spin chuck. When the current position of the first nozzle 342 is out of the reference position, the controller 900 may control the nozzle driver 346 to adjust the position of the first nozzle 342 so that the first nozzle 342 is located at the reference position. Such precise position control enables uniform and accurate application of the first liquid to the center of the substrate W, thereby improving the quality of the process. The controller 900 may continuously monitor the position of the first nozzle and perform immediate adjustment if necessary.

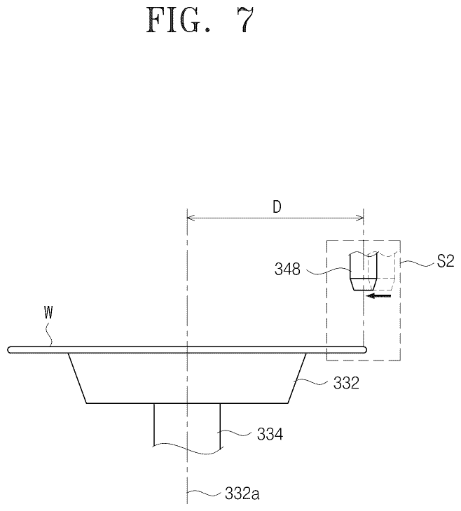

FIG. 7 is a diagram illustrating a positional relationship between the second nozzle and the spin chuck. Referring to FIG. 7, the reference position of the second nozzle 348 may be a position spaced apart from the spin chuck central axis 332a by a predetermined distance D. The reference position of the second nozzle 348 may be acquired in advance by the controller 900 before the substrate W is loaded into the treatment space. The controller 900 acquires a first image and a second image for the spin chuck 332 before the substrate W is loaded into the treatment space. Even when only the central area, which is a partial area of the spin chuck 332 is included in the first image and the second image, the position of the central axis 332a of the spin chuck may be specified through the vacuum hole 332b formed in the upper surface of the spin chuck 332. Thereafter, the information may be stored by using, as a reference position, a position spaced apart from the central axis 332a of the spin chuck by the predetermined distance D. The reference position of the second nozzle 348 may be recorded in the image acquired by the optical module 100 or may be stored in a three-dimensional coordinate. The reference position of the second nozzle 348 may be the process position of the second nozzle 348.

The controller 900 may determine the current position of the second nozzle 348 located in the second space S2 and compare the current position with the reference position. The controller 900 may compare the current position of the second nozzle 348 with the reference position and adjust the second nozzle 348 to be positioned at the reference position through the nozzle driver 346 if necessary. Accurate position control of the second nozzle 348 is important to ensure the processing quality of the edge area of the substrate. This may contribute to minimizing the edge defect of the substrate W.

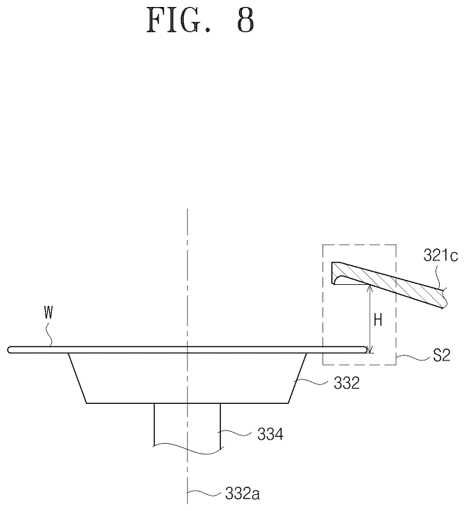

FIG. 8 is a diagram illustrating a positional relationship between the outer cup and the spin chuck. The reference position of the outer cup 321 may be a position where the end of the upper wall 321c of the outer cup is spaced apart from the upper surface of the spin chuck 332 by a predetermined height H. The reference position of the outer cup 321 may be acquired in advance by the controller 900 before the substrate W is loaded into the treatment space. The controller 900 acquires a first image and a second image for an edge area of the spin chuck 332 before the substrate W is loaded into the treatment space. The controller 900 may determine the upper surface of the spin chuck 332 and specify a position spaced apart from the upper surface by a predetermined height H as a reference position of the outer cup 321, and store the information on the reference position.

The controller 900 may determine the current position of the outer cup 321 by using the first image and the second image for the second space S2 and compare the current position with the reference position. The first image and the second image for the second space S2 include at least an end portion of the edge of the spin chuck 332 and an end portion of the upper wall 321c of the outer cup. The reference position may be defined as a height difference H between the upper surface 332a of the spin chuck and the end portion of the upper wall of the outer cup. When the current position of the outer cup 321 is different from the reference position, the controller 900 may adjust a height of the spin chuck 332 through the driver 336. However, the present invention is not limited thereto, the cup unit 320 may include a cup driving unit (not illustrated) for adjusting a height of the outer cup 321, and the controller 900 may adjust a relative height H between the outer cup 321 and the spin chuck 332 through the driver 336 or the cup driving unit. This process may maintain an appropriate distance between the spin chuck 332 and the outer cup 321, thereby preventing the first liquid or the second liquid from being scattered to the outside and keeping the processing environment clean. Such precise position control may minimize contamination that may occur during the processing of the substrate W and may increase the stability of the process.

The substrate processing apparatus according to the exemplary embodiment of the present invention may be provided to be capable of performing at least one of exemplary embodiments of FIGS. 6 to 8 described above. Furthermore, the substrate processing apparatus may be provided to perform the above-described exemplary embodiments in the middle of processing the substrate W. Accordingly, the substrate processing apparatus may determine at least the current positions of the first nozzle 342, the second nozzle 348, the spin chuck 332, and the outer cup 321 through the optical module 100 without opening the apparatus. In addition, when the determined current position is out of the reference position stored in the controller 900, the current position may be corrected in real time. Accordingly, process stability may be improved to improve product quality and yield.

In the above-described example, the present invention has been described based on the case where the first reflection mirror 140 and the second reflection mirror 150 are provided as an example. However, the present invention is not limited thereto, and one or more reflection mirrors may be further provided to further improve the accuracy of the analysis on the photographing target. In this case, the additional reflection mirror may be provided to view the photographing target from more various angles or to expand the photographing area of the optical module 100. As the reflection mirror is additionally provided, a structure of the frame 110, a position and a rotation range of the direction changing mirror 130, and the like may be changed and provided.

In addition, in the above-described example, the present invention has been described based on the case where the reference position of the first nozzle 342 is the position on the center axis 332a of the spin chuck as an example. However, the present invention is not limited thereto, and the reference position of the first nozzle 342 may be a position where the first liquid is discharged to the center of the substrate W, and may be expressed in preset three-dimensional coordinates including x, y, and z.

In addition, in the above-described example, the present invention has been described based on the case where the reference position of the second nozzle 348 is the position spaced apart from the central axis 332a of the spin chuck by the predetermined distance D as an example. However, the present invention is not limited thereto, and the reference position of the second nozzle 348 may be a position where the second liquid is discharged to the edge of the substrate W, and may be expressed in preset three-dimensional coordinates including x, y, and z.

In addition, in the above-described example, the present invention has been described based on the case where the optical mirrors 130, 140, and 150 are provided as the means of changing a path of light as an example. However, the present invention is not limited thereto, and any means, such as a beam splitter or a prism mirror, is sufficient provided that it is possible to change the path of light.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. An apparatus for processing a substrate, the apparatus comprising:
a housing providing an inner space;
a cup unit placed in the inner space and providing a treatment space for processing the substrate;
a spin chuck configured to support the substrate in the treatment space;
a nozzle unit configured to supply a treatment liquid to the substrate supported on the spin chuck; and
an optical module for photographing the inner space,
wherein the optical module includes:
a camera;
a direction changing mirror placed in a position facing the camera;
a first reflection mirror;
a second reflection mirror; and
a mirror driver configured to drive the direction changing mirror, and
the direction changing mirror is provided so as to be position-changeable between a first position and a second position,
the first position is a position where the camera photographs the inner space through the first reflection mirror, and
the second position is a position where the camera photographs the inner space through the second reflection mirror.

2. The apparatus of claim 1, wherein the camera and the direction changing mirror are arranged in a first direction, and
the first reflection mirror and the direction changing mirror, and the direction changing mirror and the second reflection mirror are each arranged in a second direction perpendicular to the first direction.

3. The apparatus of claim 2, wherein the first reflection mirror, the direction changing mirror, and the second reflection mirror are sequentially arranged along the second direction.

4. The apparatus of claim 2, wherein the mirror driver rotates the direction changing mirror about the first direction as an axis.

5. The apparatus of claim 4, wherein the optical module includes:
a rotating plate provided to be rotatable; and
a support fixedly installed on the rotating plate, and
the support has an inclined surface,
the inclined surface is provided to face the camera, and
the direction changing mirror is installed on the inclined surface.

6. The apparatus of claim 5, wherein the optical module further includes a frame having a space in which the first reflection mirror, the second reflection mirror, and the direction changing mirror are disposed, and
the frame has an opening formed at each of a position facing the first reflection mirror and a position facing the second reflection mirror.

7. The apparatus of claim 6, wherein the nozzle unit includes:
a first nozzle configured to discharge a first liquid to a center of the substrate supported by the spin chuck; and
a second nozzle configured to discharge a second liquid to an edge of the substrate supported by the spin chuck,
the optical module is provided to photograph the first nozzle located in a first space and the second nozzle located in a second space,
the first space includes a position where the first liquid is discharged from the first nozzle, and
the second space includes a position where the second liquid is discharged from the second nozzle.

8. The apparatus of claim 7, wherein the first liquid is photoresist, and
the second liquid is a removal liquid that removes the first liquid from an edge area of the substrate.

9. The apparatus of claim 7, wherein the first space includes a central axis of the spin chuck.

10. The apparatus of claim 7, wherein the first reflection mirror and the second reflection mirror are each rotatably provided, and
the first space or the second space is photographed according to rotation of the first reflection mirror and the second reflection mirror.

11. The apparatus of claim 10, wherein the first reflection mirror and the second reflection mirror rotate about a third direction as an axis, and the third direction is perpendicular to the first direction and the second direction.

12. The apparatus of claim 1, wherein the camera includes:
a lens; and
an image sensor configured to form an image, and
the lens is a telephoto lens.

13. The apparatus of claim 7, further comprising:
a controller,
wherein the nozzle unit further includes a nozzle driver configured to drive the first nozzle and the second nozzle,
the controller controls the optical module to determine a current position of at least one of the first nozzle and the second nozzle by photographing at least one of the first nozzle and the second nozzle, and when the current position does not match a reference position, the controller controls the nozzle driver to move at least one of the first nozzle and the second nozzle from the current position to the reference position, and
the reference position is a preset position.

14. An optical module comprising:
a frame having an inner space;
a camera installed in the frame;
a direction changing mirror placed in a position facing the camera in the inner space;
a first reflection mirror provided to be rotatable in the inner space;
a second reflection mirror provided to be rotatable in the inner space; and
a mirror driver configured to drive the first reflection mirror, the second reflection mirror, and the direction changing mirror,
the frame has an opening formed at each of a position facing the first reflection mirror and a position facing the second reflection mirror,
the first reflection mirror and the second reflection mirror are rotated to change an area photographed by the camera,
the direction changing mirror is provided so as to be position-changeable between a first position and a second position,
the first position is a position where the camera photographs an area through the direction changing mirror and the first reflection mirror, and
the second position is a position where the camera photographs an area through the direction changing mirror and the second reflection mirror.

15. The optical module of claim 14, wherein the camera and the direction changing mirror are arranged in a first direction, and
the first reflection mirror and the direction changing mirror, and the direction changing mirror and the second reflection mirror are each arranged in a second direction perpendicular to the first direction.

16. The optical module of claim 15, wherein the first reflection mirror and the second reflection mirror rotate about a third direction as an axis, and the third direction is perpendicular to the first direction and the second direction, and
the direction changing mirror rotates about the first direction as an axis.

17. The optical module of claim 16, further comprising:
a rotating plate provided to be rotatable; and
a support fixedly installed on the rotating plate, and
the support has an inclined surface,
the inclined surface is provided to face the camera, and
the direction changing mirror is installed on the inclined surface.

18. An apparatus for processing a substrate, the apparatus comprising:
a housing providing an inner space;
a cup unit placed in the inner space and providing a treatment space for processing the substrate;
a spin chuck configured to support the substrate in the treatment space;
a nozzle unit configured to supply a treatment liquid to the substrate supported on the spin chuck; and
an optical module configured to photograph the inner space,
the optical module includes:
a frame having a space therein;
a camera provided within the frame;
a direction changing mirror placed in a position facing the camera;
a first reflection mirror provided to be rotatable;
a second reflection mirror provided to be rotatable;
a mirror driver configured to drive the first reflection mirror, the second reflection mirror, and the direction changing mirror;
a rotating plate provided to be rotatable; and
a support fixedly installed on the rotating plate, and
the support has an inclined surface,
the inclined surface is provided to face the camera,
the direction changing mirror is installed on the inclined surface,
the frame has an opening formed at each of a position facing the first reflection mirror and a position facing the second reflection mirror,
the first reflection mirror and the second reflection mirror are rotated to change an area photographed by the camera,
the direction changing mirror is provided so as to be position-changeable between a first position and a second position,
the first position is a position where the camera photographs the inner space through the first reflection mirror, and
the second position is a position where the camera photographs the inner space through the second reflection mirror, and
the camera and the direction changing mirror are arranged in a first direction, and
the first reflection mirror and the direction changing mirror, and the direction changing mirror and the second reflection mirror are each arranged in a second direction perpendicular to the first direction,
the first reflection mirror and the second reflection mirror rotate about a third direction as an axis, and the third direction is perpendicular to the first direction and the second direction, and
the direction changing mirror rotates about the first direction as an axis.

19. The apparatus of claim 18, wherein the nozzle unit includes:
a first nozzle configured to discharge a photoresist to a center of the substrate supported by the spin chuck; and
a second nozzle configured to discharge a removal liquid that remove the photoresist applied on an edge of the substrate supported by the spin chuck,
the optical module is provided to photograph the first nozzle located in a first space and the second nozzle located in a second space,
the first space includes a position where the photoresist is discharged from the first nozzle, and
the second space includes a position where the removal liquid is discharged from the second nozzle.

20. The apparatus of claim 19, wherein the nozzle unit further includes a nozzle driver configured to drive the first nozzle and the second nozzle,
the controller controls the optical module to photograph at least one of the first nozzle and the second nozzle to determine a current position of at least one of the first nozzle and the second nozzle,
when the current position does not match a reference position, the controller controls the nozzle driver to move at least one of the first nozzle and the second nozzle from the current position to the reference position, and
the reference position is a position on a central axis of the spin chuck.
